(19) United States
(12) Patent Application Publication
(10) Pub. No.: US 2026/0052956 A1
(43) Pub. Date: Feb. 19, 2026

(54) REDUCING THERMAL BOW SHIFT

(71) Applicant: Lam Research Corporation, Fremont, CA (US)

(72) Inventors: Jeongseok Ha, Portland, OR (US); Xin Yin, Beaverton, OR (US); Michael Anthony Chan, Tigard, OR (US); Fayaz A. Shaikh, Lake Oswego, OR (US)

(73) Assignee: Lam Research Corporation, Fremont, CA (US)

(21) Appl. No.: 19/100,499

(22) PCT Filed: Jul. 31, 2023
(86) PCT No.: PCT/US2023/029129

§ 371 Date: Jan. 31, 2025

Related U.S. Application Data
(60) Provisional application No. 63/370,556, filed on Aug. 5, 2022.

(51) Int. Cl. H01L 21/02; H01L 21/324; H01L 21/67

(52) U.S. Cl. CPC H01L 21/02016; H01L 21/02164; H01L 21/0217; H01L 21/022; H01L 21/324; H01L 21/67098

(57) ABSTRACT

Provided are methods and structures for keeping the integrity of layers deposited on a semiconductor wafer through a thermal cycle. Deposition of a second backside layer, or a cap, with an internal stress opposite to a first backside layer may be used to reduce bow shift of a wafer during a thermal cycle. The first backside layer may have a tensile internal stress or a compressive internal stress. The second backside layer has an internal stress opposite to the first backside layer. Each of the backside layers may be deposited by a backside deposition apparatus.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In semiconductor processing, it may be desired that a wafer remains substantially flat. However, during normal operations, a wafer may experience wafer bow. The wafer bow may cause issues such as inability to be properly clamped by an electrostatic chuck, inability to be held by a wafer handler, and pattern transfer issues during photolithography issues, among others. Processes have been developed to manage wafer bow by keeping the wafer flat within process tolerances. One process includes depositing a film on the backside of the wafer to counteract any stress that may be causing the wafer to bow. While this stress from the deposited backside film may keep the wafer substantially flat, the additional backside material may cause the wafer to further shift during normal wafer processing and potentially damage the wafer and/or cause wafer handling problems in subsequent process operations. Discussed herein are improvements related to improving the integrity of the wafer, reducing the potential of damage to the wafer, and reducing the risk of a wafer handling problem during subsequent wafer processing.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Aspects of this disclosure pertain to methods of processing a substrate during fabrication of an electronic device. Such methods may be characterized by the following operations: (a) depositing one or more frontside layers on a frontside of the substrate, wherein the one or more frontside layers induce a bow in the substrate; (b) depositing a first backside layer on a backside of the substrate, wherein the first backside layer reduces the bow in the substrate, wherein the first backside layer and the one or more frontside layers have internal stresses of a first type; (c) depositing a second backside layer over the first backside layer, wherein the second backside layer has an internal stress of a second type, which is opposite the first type or is neutral; and (d) after (c), exposing the substrate to a thermal process that increases the substrate's temperature to at least about 600° C.

In some embodiments, at least one of the one or more frontside layers comprise a hardmask. In some embodiments, the one or more frontside layers comprise a stack of alternating layers (e.g., about 100 or more). As examples, the stack may comprise alternating oxide layers and nitride or polysilicon layers.

In some cases, the bow of the substrate is about 300 μm or more, or even about 400 μm or more. In some embodiments, the internal stress of the first type is a tensile stress and the internal stress of the second type is a compressive stress. In some cases, a first bow magnitude that would be produced by the first backside layer is larger, if uncompensated, than a second bow magnitude, if uncompensated, that would be produced by the second backside layer.

In certain embodiments, the first backside layer comprises silicon nitride. In certain embodiments, the first backside layer has a thickness of about 0.1 μm to about 5 μm. In certain embodiments, the second backside layer comprises silicon oxide. In certain embodiments, the second backside layer has a thickness of about 0.01 μm to about 1 μm.

In some applications, the thermal process in (d) is an annealing process. In some applications, the thermal process in (d) comprises deposition of a hardmask on the frontside of the substrate.

Another aspect of this disclosure pertains to substrates characterized by the following features: (a) one or more frontside layers on a frontside of the substrate; (b) a first backside layer on a backside of the substrate, wherein the first backside layer and the one or more frontside layers have internal stresses of a first type; and (c) a second backside layer over the first backside layer, wherein the second backside layer has an internal stress of a second type, opposite that of the internal stress or neutral.

In some embodiments, if from the one or more frontside layers of a substrate are not compensated by the first backside layer, the substrate has a bow of about 300 um or more or even about 400 μm or more.

In some implementations, at least one of the one or more frontside layers of a substrate is a hardmask. In some implementations, the one or more frontside layers comprise a stack of about 100 or more alternating layers (e.g., alternating oxide layers and nitride or polysilicon layers). In some embodiments, the internal stress of the first type is a tensile stress and the internal stress of the second type is a compressive stress. In some embodiments, a first bow magnitude that would be produced by the first backside layer, if uncompensated, is larger than a second bow magnitude, if uncompensated, that would be produced by the second backside layer.

In certain embodiments, the first backside layer of a substrate comprises silicon nitride. In certain embodiments, the first backside layer has a thickness of about 0.1 μm to about 5 μm. In certain embodiments, the second backside layer of a substrate comprises silicon oxide. In certain embodiments, the second backside layer has a thickness of about 0.01 μm to about 1 μm.

Other aspects of this disclosure pertain to apparatus for semiconductor processing. Such apparatus may be characterized by the following features: (a) a process chamber; (b) a substrate support within the process chamber; (c) a showerhead; (d) a gas source fluidically connected to the showerhead; and (e). a controller. The controller may be configured (e.g., designed or programmed) to cause: (i) receiving a substrate comprising one or more frontside layers that cause bow in the substrate; (ii) depositing a first backside layer on a backside of the substrate, which first backside layer reduces bow in the substrate, wherein the first backside layer and one or more frontside layers have internal stresses of a first type; and (iii) depositing a second backside layer over the first backside layer, wherein the second backside layer has a neutral internal stress or an internal stress of a second type, opposite that of the first type.

In certain embodiments, the bow in a received substrate is about 300 μm or more or about 400 μm or more. In certain embodiments, the first backside layer and the second backside layer of the received substrate are deposited by plasma-enhanced chemical vapor deposition.

In certain embodiments, at least one of the one or more frontside layers or a received substrate is a hardmask. In certain embodiments, the one or more frontside layers of a received substrate comprise a stack of about 100 or more alternating layers. As an example, the stack comprises alternating oxide layers and nitride or polysilicon layers.

In certain embodiments, the internal stress of the first type is a tensile stress and the internal stress of the second type is a compressive stress. In applications, the first backside layer of a received substrate would produce a first bow magnitude that, if uncompensated, is larger than a second bow magnitude that, if uncompensated, would be produced by the second backside layer.

In certain embodiments, the first backside layer of a received substrate comprises silicon nitride. In certain embodiments, the first backside layer has a thickness of about 0.1 μm to about 5 μm. In certain embodiments, the second backside layer of a received substrate comprises silicon oxide. In certain embodiments, the second backside layer has a thickness of about 0.01 μm to about 1 μm.

These and other features of the disclosure will be described herein, sometimes with reference to the associated drawings.

### BRIEF DESCRIPTION OF THE DRAWINGS

FIGS. 1A and 1B show examples of unbowed and bowed semiconductor wafers on an electrostatic chuck.

FIGS. 2A to 2C show example profile views of bow of a wafer.

FIGS. 3A to 3D show a cross sectional view of example wafers before and after a thermal cycle.

FIGS. 4A to 4C show example profile views of bow of a wafer.

FIGS. 5A and 5B show a cross sectional view of an example wafer before and after a thermal cycle.

FIG. 6 is a process flow diagram illustrating certain operation in semiconductor wafer processing.

FIG. 7 is a process flow diagram illustrating certain operation in semiconductor wafer processing.

FIG. 8 shows an example cross section of a semiconductor wafer during semiconductor processing according to various embodiments.

FIG. 9 is a process flow diagram illustrating certain operation in semiconductor wafer processing.

FIG. 10 is a process flow diagram illustrating certain operation in semiconductor wafer processing.

FIGS. 11A-C are schematic depictions of example cross section of a semiconductor wafer during semiconductor processing according to various embodiments.

FIGS. 12A and 12B show a block diagram of an example substrate processing system.

FIG. 13A shows an example cross section of an edge of a shower-pedestal.

FIG. 13B shows a top view of an example carrier ring.

FIG. 14 shows a schematic of an example process system that may be used to perform the methods described herein.

### DETAILED DESCRIPTION

### Terminology

The following terms are used throughout the instant specification:

The terms “semiconductor wafer,”wafer,“substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

“Wafer bow” as used herein may refer to a deformation of a wafer. The deformation may have radial and/or azimuthal components. Examples of types of wafer bow include dome shapes, dish shapes, and potato chip shapes. Wafer bow may occur during fabrication, for example, as a result of stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps (e.g., photolithography) may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

“Bow shift” refers to a change in the amount of wafer bow during a semiconductor process. A wafer that has experienced a bow shift may retain a particular bow direction, e.g., dome shape, dish shape, etc., but change the bow's magnitude. In some cases, a bow shift may change the direction of the bow, e.g., the wafer may initially be a dome shape and after experiencing bow shift, the wafer may have a dish shape. Examples of semiconductor processes that may induce bow shift include deposition of material, etch processes, and thermal processing, e.g., annealing. Bow shift may be measured in various ways. In some cases, bow shift is described by the ratio final bow to original wafer bow. The original bow may be set at any point in the processing, but unless stated otherwise, the original bow used to measure bow shift is the bow after frontside layers have been deposited but before any backside layers have been deposited.

“Thermal Cycle” or “thermal process” refers to an operation subjecting a wafer to elevated temperature for a period of time. Examples of device fabrication operations that may include a thermal cycle include thermal annealing, formation of a hardmask, material deposition, and etching. In the context of this disclosure, a thermal cycle is often performed after a bow-compensating backside layer has been deposited. A high temperature experienced during a thermal cycle may be about 650 C or more or between about 650 and 1100° C. The duration of exposure to the high temperature may be any length of time. In some embodiments, the duration is at least about 50 seconds or at least about 100 seconds or at least about 200 seconds.

### Bowed Wafers

Semiconductor device fabrication often involves deposition of a stack of layers on a wafer substrate. Typically, most deposition and other processing to form the devices occurs on one side of the substrate, often referred to as the front face or frontside of a wafer. As the deposited layers build up, they can introduce stress in the wafer. A large net compressive or tensile stress can cause the wafer to bow, which is undesirable.

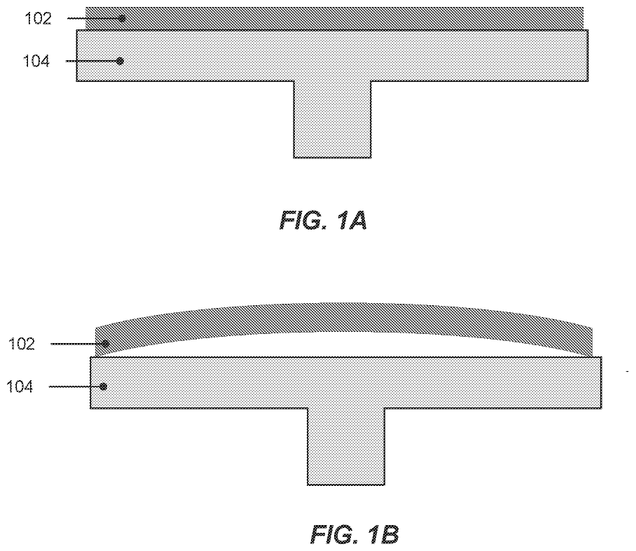

Bowing is especially likely to occur where large stacks of materials are deposited, for example, in the context of 3D-NAND devices. Where bowing is significant, it can deleteriously affect subsequent processing steps. For instance, the wafer may fail to chuck correctly if the bowing is too great. FIG. 1A and 1B show a wafer on an electrostatic chuck. FIG. 1A shows a wafer 102 on an electrostatic chuck 110. When the wafer 102 is substantially flat for purposes of a particular process operation, e.g., having a bow of about 100 μm or less, the wafer may be properly clamped, securing the wafer for subsequent processing steps. FIG. 1B shows a bowed wafer 104 on the electrostatic chuck 110. When the bow is significant, the wafer may fail to secure properly on the electrostatic chuck. Wafer bow may cause other problems. For example, certain processing steps (e.g., photolithography) are very precise and produce poor results if the wafer is not substantially flat. The problem may be manifest as lithography defocus.

One example stack that may cause these problems is a stack having alternating layers of oxide and nitride (e.g., silicon oxide/silicon nitride/silicon oxide/silicon nitride, etc.). Another example of a type of stack likely to cause bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride.

The materials in the stacks may be deposited through chemical vapor deposition (CVD) techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the frontside of the wafer.

The frontside stacks may be deposited to any number of layers and thicknesses. In a typical example, the stack includes between about 32-72 layers, and has a total thickness of about 2 μm to about 4 μm. The stress induced in the wafer by the stack may be about −500 MPa to about +500 MPa, resulting in a bow that is frequently about 200 μm to about 400 μm (for a 300 mm wafer), and even greater in some cases. However, modern IC fabrication techniques may produce substrates having frontside layers with much higher internal stresses compared to previous nodes. The frontside may have larger stacks, for example, stacks may be upwards of a 1000 layers. In another example, reduced etch selectivity has led to thicker masks. These stacks may have a thickness of about 4 μm to 12 μm.

Various techniques have been devised for combatting bowing. When bowing is more severe, deposition processes may be tuned to reduce or counteract internal stresses in deposited layers. However, any such tuning should not interfere with process requirements for fabricating devices. One commonly used technique to counteract bowing deposits a film on the back side of the wafer.

Backside deposition may form a high-stress film. If the backside layer has the same type of internal stress (tensile or compressive) and of comparable magnitude to the internal stress created on the frontside, the backside film effectively counteracts and corrects the bow.

Examples of backside films used to counteract bow include the following: amorphous silicon, silicon oxide, silicon nitride, and silicon oxynitride. Current backside films have high internal stress and are able to mitigate the stresses imparted on the wafer from the frontside layers to reduce or eliminate the wafer bow. Generally, backside layers are made of films with high stress.

Until relatively recently, the backside film thickness remained relatively thin (e.g., <2 μm) because the bow caused by depositing material on the frontside was relatively modest. Thus, downstream processes at previous technology nodes did not normally experience issues addressed by embodiments herein. However, modern IC fabrication techniques may produce substrates having frontside layers that produce much more severe wafer bow compared to previous nodes. For example, some modern processes use thick hardmask layers in operations where the etch selectivity between the hardmask and etched material is limited but yet deep trenches or vias are etched. In another example, frontside stacks have increased the number of layers. For example, in previous nodes stacks may have been about 32 to about 72 layers. Now, stacks may have hundreds or even thousands of layers, increasing the thickness of the frontside layer and the internal stress.

Due to the increasing magnitude of wafer bow, thicker backside films must be deposited to compensate for wafer bow. This has caused certain issues. For example, when the wafer is subjected to a subsequent thermal cycle, the wafer bow compensating layer on the backside may undergo a significant bow shift. With thicker backside layers, the bow shift during a thermal cycle may be larger. For example, a bow shift may be about 30% or even up to about 60% of the original bow. As a result of such large bow shifts, cracking may occur in the deposited layers on the wafer. And, even if cracking does not result, the bow shift may induce a new bow in the wafer, which hinders downstream processing.

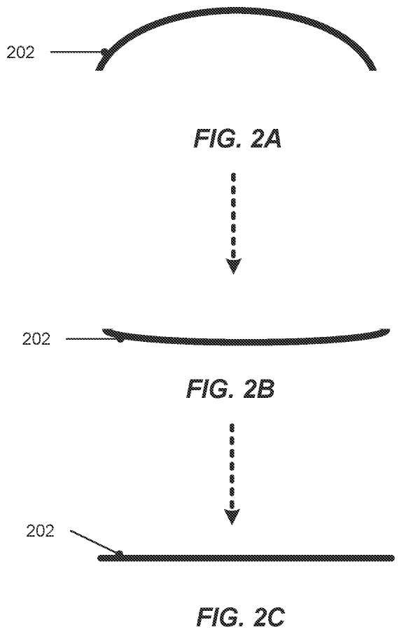

FIGS. 2A-2C show profile views of a wafer's bow 202 after different processing events. These figures illustrate the challenge of bow shift in processing. FIG. 2A shows the wafer bow 201 2after one or more frontside layers have been deposited. The frontside layer has an internal stress, e.g., a tensile internal stress or a compressive internal stress. This internal stress causes the wafer to bow as shown in FIG. 2A. In the example shown, the wafer bow 201 is a dome shape.

FIG. 2B shows the wafer after a backside layer is deposited onto the wafer. In the embodiment shown, the backside layer has an internal stress that is the same type as the internal stress of the frontside layer, e.g., if the frontside layer has a tensile internal stress then the backside layer also has a tensile internal stress. By having the same type of internal stress, the wafer bow 201 is reduced or eliminated. In an ideal case as shown in FIG. 2B, to prepare for subsequent bow shift, the backside layer is so thick that the direction of the bow changes, such that the wafer goes from a dome shape in FIG. 2A to a dish shape in FIG. 2B. In the depicted example, the magnitude of the bow from the backside layer is slightly greater than the bow from the frontside layer. Thus, in some cases, as depicted in FIG. 2B, the backside layer overcompensates for the bow induced by the frontside layer(s). This may be to account for an expected impact of a subsequent thermal cycle.

FIG. 2C shows the wafer 202 after undergoing a thermal cycle e.g., annealing. The thermal cycle causes a bow shift in the wafer 202. As shown, the wafer in FIG. 2B has a dish shaped bow and after the annealing process, as shown in FIG. 2C, the wafer is substantially flat. In some embodiments, which will be discussed in more detail below, the bow shift during a thermal cycle may cause cracking of the frontside layer, the backside layer, or both the frontside layer and the backside layer.

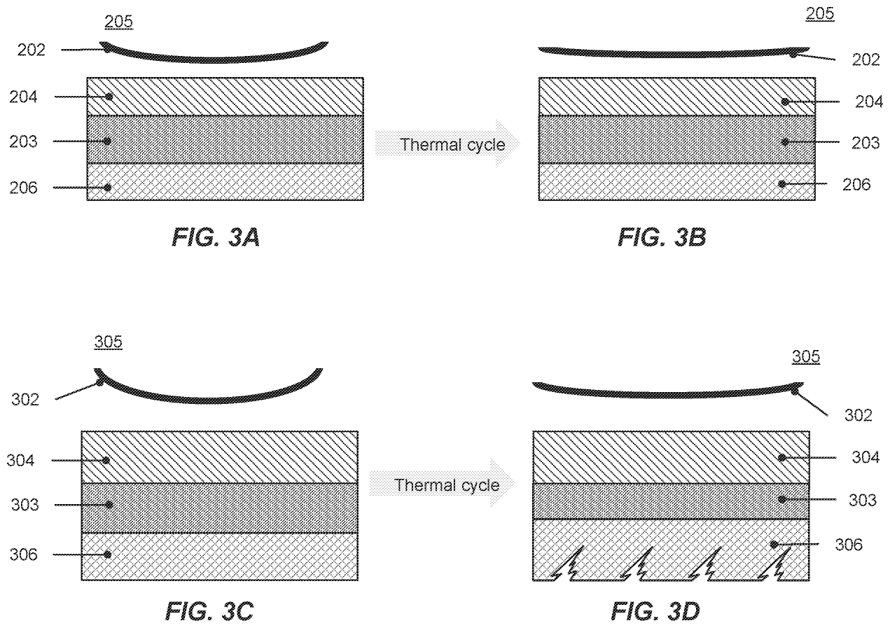

FIGS. 3A through 3D show two different bowed wafers (wafer 202 and wafer 302) before and after a thermal cycle. Each figure shows a small segment of the wafer in cross-section and a profile view of the entire wafer. The profile views are identified by reference numerals 205 and 305. As shown in FIGS. 3A and 3B, wafer 202 has a main structure 203 (e.g., a single crystal silicon substrate), a frontside layer 204, and a backside layer 206. Similarly, as shown in FIGS. 3C and 3D, wafer 302 has a main structure 303 (e.g., a single crystal silicon substrate), a frontside layer 304, and a backside layer 306.

FIGS. 3A and 3B illustrate wafer 202 with a frontside layer 204 having modest impact on bow (e.g., frontside layer 204 is relatively thin) while FIGS. 3C and 3D illustrate wafer 302 with a frontside layer 304 having more pronounced bow impact. FIG. 3A and FIG. 3C show their respective wafers 202 and 302 before a thermal cycle. As shown in the profile view 205, the bow of wafer 202 with a thinner frontside layer 204 (FIG. 3A) is less pronounced than the bow in wafer 302 with the thicker frontside layer (FIG. 3C).

As wafer 302 undergoes a thermal cycle, a wafer may go through a bow shift. As shown in the profile view 205 of FIG. 3B, the wafer 202 has a reduction in bow. The bow shift may put additional stress on each of the wafer 202, the frontside layer 204, and the backside layer 206. If the bow shift is below a defined threshold or tolerance for a particular process (e.g., about 100 μm or less), then the bow may be manageable (e.g., the wafer can be handled without problems) and the wafer 202, the frontside layer 204 and the backside layer 206 may remain intact without any cracks as shown in FIG. 3B.

FIGS. 3C and 3D illustrate wafer 302 with frontside layer 304 having a more pronounced bow (e.g., frontside layer 304 is relatively thick) compared to the wafer in FIGS. 3A and 3B. In the example shown, the bow of the wafer 302 in FIG. 3C is greater than the bow of the wafer 202 in FIG. 3A.

As shown in the example in FIG. 3D, as the wafer 302 undergoes a thermal cycle, the wafer may go through a significant bow shift. In the example, the wafer undergoes a relatively large bow shift, e.g., about 40 μm or more. The bow shift from the thermal cycle may cause cracking in one of the layers, damaging the wafer 302 and/or introducing wafer handling issues in subsequent process operations. In the example shown, the backside layer 306 has cracks within it. In particular, a thermal cycle may induce cracks on tensile backside layers when the tensile backside layer has a bow value above particular threshold. In some cases, cracks are not observed with compressive or neutral backside layers.

Disclosed herein are methods, systems, and techniques for maintaining the integrity of each of the deposited layers, particularly a backside layer, on a wafer during a thermal cycle. In particular, the wafer may have a second backside layer deposited on top of a first backside layer. By choosing properties of the second backside layer such as internal stress type (e.g., compressive or neutral versus tensile) and thickness, the second backside layer may reduce the bow shift during a thermal cycle and reduce the probability of cracks forming on deposited layers. The second backside layer is sometimes referred to as a “cap” herein. A cap is a backside layer deposited on another backside layer that has an internal stress opposite to the previous backside layer. The cap can reduce the bow shift of a wafer during a thermal cycle and reduce the probability of cracking of layers that may occur due to bow shift.

The first backside layer deposited is used to counteract the wafer bow caused by a frontside layer deposited onto the wafer. When the frontside layer has a tensile internal stress, the first backside layer may also have a tensile internal stress. Similarly, when the frontside layer has a compressive internal stress, the first backside layer may also have a compressive internal stress. The second backside layer, or the cap, is deposited on the first backside layer and has a stress that counteracts the first backside layer stress. Since both layers are on the same side (the backside) of the wafer, the layers are of opposite types. For example, when the first backside layer is a tensile layer, the second backside layer is a compressive layer. In certain embodiments, the second backside layer has a magnitude of internal stress that is less than the magnitude of the internal stress of the first backside layer. For example, the magnitude of the internal stress of the second backside layer may be about 20% or less than the magnitude of the internal stress of the first backside layer. In some embodiments, the magnitude of bow induced the second backside layer is less than the magnitude of bow induced by the first backside layer. By having the first and second backside layers with opposite internal stress types, the wafer undergoes a smaller bow shift during thermal cycles, thereby reducing the probability of cracking of any of the layers. In some embodiment, the cap or second backside layer has a neutral internal stress: i.e., the internal stress is neither tensile nor compressive.

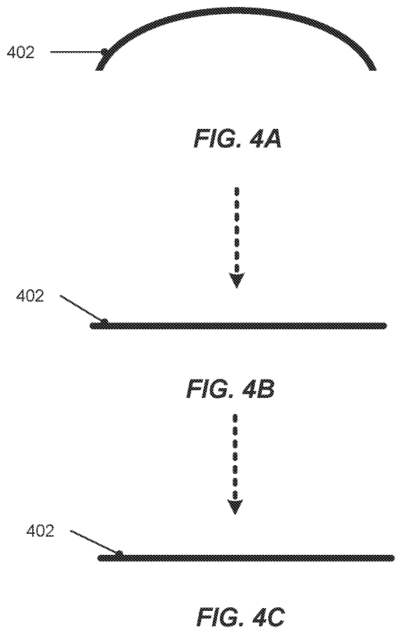

FIGS. 4A-4C shows profile views of a wafer's bow 401 with a second backside layer after different processing events. FIG. 4A shows the wafer bow 401 after a frontside layer (not shown) has been deposited. The frontside layer has an internal stress which causes the wafer to bow.

FIG. 4B shows the wafer bow 401 after two backside layers (not shown), a first backside layer and a second backside layer, are deposited onto the wafer. The first backside layer is deposited closer to the wafer and has an internal stress as the same type as the internal stress of the frontside layer. The second backside layer is deposited on top of the first backside layer and is an opposite type of the internal stress of the frontside layer. For example, if the frontside layer is has a tensile internal stress then the first backside layer has a tensile internal stress, and the second backside has a compressive internal stress. The first backside layer counteracts the bow of the wafer caused by the frontside layer. The second backside layer may add to the bow of the wafer caused by the frontside layer. Each of the backside layers may be chosen such that the wafer bow 401 is minimized. As shown in FIG. 4B, the backside layers are chosen such that after the deposition of each of the layers, the wafer bow 401 is substantially flat.

FIG. 4C shows the wafer bow 401 after undergoing an exposure to a thermal cycle. Generally, as shown above in FIG. 2C, the thermal cycle causes a bow shift in the wafer4. However, by adding the second backside layer with internal stress that counteracts the stress caused by the first backside layer, the bow shift is reduced. In some cases, as shown in the example in FIG. 4C, there is no bow shift. Thus, after the wafer undergoes a thermal cycle, the wafer bow 401 remains substantially flat.

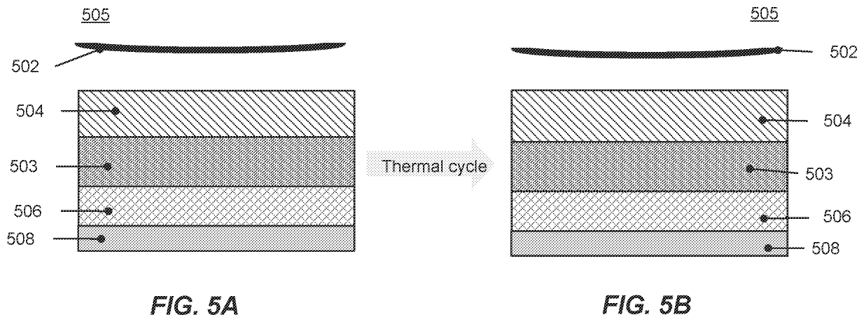

FIGS. 5A and 5B show a wafer 502 before and after a thermal cycle. The wafer 502 has a main structure 503 (e.g., a single crystal silicon substrate), a frontside layer 504, a first backside layer 506, and a second backside layer 508. Each figure shows a small segment of the wafer in cross-section and profile view Sof the wafer 502. The profile views are identified by reference numerals 505.

The frontside layer 504 in FIGS. 5A and 5B have a frontside layer with a more pronounced internal stress comparable to the frontside layer shown in FIGS. 3C and 3D. However, in FIG. 5, the wafer 502 has two backside layers, a first backside layer 506 and a second backside layer 508, a cap. Similar to the example in FIGS. 4A through 4C, the frontside layer 504 has a first type of internal stress (tensile or compressive), the first backside layer 506 has the same type of internal stress, and the second backside layer 508 has an internal stress opposite to the first type of internal stress. In a first example, the frontside layer 504 has a tensile internal stress, the first backside layer 506 has a tensile internal stress, and the second backside 508 has a compressive internal stress. In a second example, the frontside layer 504 has a compressive internal stress, the first backside layer 506 has a compressive internal stress, and the second backside 508 has a tensile internal stress.

FIG. 5B shows the wafer 502 after undergoing a thermal cycle. As shown in the profile view 505, there is no bow shift after the thermal cycle. In some embodiments, the thermal cycle may cause a minimal bow shift, e.g., about 10 μm or less. Despite having a more pronounced bow induced by the frontside layer, similar to the frontside layer 304 in FIGS. 3C and 3D, there is no cracking to the frontside layer 504, the first backside layer 506, or the second backside layer 508. By having the two backside layers each with an opposite type of stress compared to the other, 555 the bow shift may be reduced during a thermal cycle for wafers 5with thick frontside layers, thus reducing the occurrence of cracking on any of the layers.

As mentioned, wafer bow may be caused by frontside processing. In some embodiments, frontside processing may deposit a material or stacks of materials with an internal stress, either compressive stress or tensile stress. The stacks of material may be multiple-layer stacks. In some embodiments, multiple-layer stacks may have about 100 or more layers. In some embodiments, multiple-layer stacks may have about 500 or more layers. In some embodiments, the multiple-layer stacks may have about 1000 or more layers. The internal stress of the deposited material or stacks of material may have a magnitude from 0 MPa to about 500 MPa. The stress may be a tensile stress or a compressive stress. The stress may cause significant wafer bowing. For example, the wafer may have wafer bow of about 150 μm or above, e.g., about 300 μm and above, about 400 μm and above. One example stack that may cause these problems is a stack having alternating layers of oxide and nitride (e.g., silicon oxide/silicon nitride/silicon oxide/silicon nitride, etc.). Another example of a type of stack likely to result in bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride. The materials in the stacks may be deposited through chemical vapor deposition techniques such as PECVD, LPCVD, MOCVD, ALD, PEALD, or DMD, etc. These examples are not intended to be limiting.

Another cause of wafer bow may be frontside processing which use thick hardmasks with limited etch selectivity. In these embodiments, at least one of the one or more frontside layers is a hardmask. The thick hardmasks may have an internal stress similar to those described above, e.g., have a magnitude of 0 MPa to about 500 MPa. The stress caused by the hardmask may be tensile stress or compressive. The thick hardmasks may cause wafers to have a significant wafer bow, e.g., about 150 μm or more.

The backside layer thickness is typically proportional to wafer bow. Greater wafer bow values require thicker backside compensating layers. Wafers with wafer bow of about 300 μm or greater, e.g., about 400 μm or greater, may require a backside film that is so thick that it may be susceptible to cracking. A backside film may have an internal stress able to counteract the internal stress from a frontside layer. The backside film may be deposited using a CVD, PECVD, ALD, PEALD, or epitaxial growth process. The backside film may be deposited in a backside deposition apparatus.

To combat wafer bow caused by a frontside layer with an internal tensile force, a tensile film may be used for the backside film. Tensile films may be formed using specific materials and/or processing conditions. Example materials used to make tensile films include silicon nitrides (SiN), silicon oxynitrides, and polymer layers. Tensile films can be deposited using CVD or PECVD techniques.

To combat wafer bow caused by a frontside layer with an internal compressive force, a compressive film may be used for the backside film. Compressive films may be formed using specific materials and/or processing conditions. Example materials used to make compressive films include silicon oxides (SiOₓ), silicon nitrides, aluminum oxides, aluminum nitrides, and polysilicon. Compressive films can be deposited using CVD or PECVD techniques.

As explained, during wafer processing, a wafer may be subjected to a thermal cycle. The thermal cycle subjects the wafer to an elevated temperature. It may be caused by any of various process operations. The thermal cycle may induce a bow shift of the wafer. Generally, a wafer with a large bow may experience a relatively large bow shift. Large bow shifts have an increased chance of cracking layers deposited on the wafer, e.g., the backside layer. One example of a thermal cycle is annealing of the wafer. Another example of a thermal cycle is depositing a material such as a hardmask on the frontside of the wafer. For example, deposition make cause a thermal cycle when it takes place at temperatures above about 650° C. or above about 850° C. In another example, thermal annealing may subject the wafer to a thermal cycle, for example at temperatures up to about 1100° C.

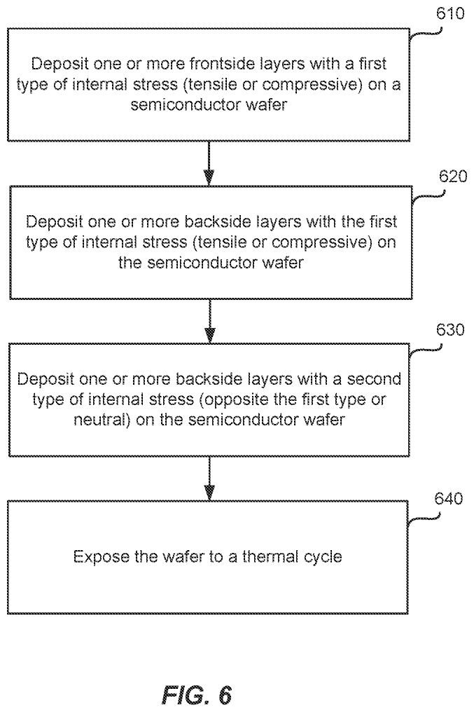

FIG. 6 shows a first example process using deposition of a first backside layer with a cap. FIG. 6 starts with depositing one or more frontside layers with a first type (tensile or compressive) of internal stress on a wafer in an operation 610. The internal stress from the frontside layer may cause the wafer to bow. In some embodiments, the frontside layer may have a tensile internal stress. In some embodiments, the frontside layer may have a compressive internal stress. In some embodiments, the wafer of the bow is about 300 μm or more, e.g., about 400 μm or more.

Once a frontside layer is deposited onto the wafer, a first backside layer having an internal stress of the first type is deposited onto the wafer in an operation 620. In other words, the internal stress of the backside layer is the same type of internal stress of the frontside layer deposited in operation 610. For example, if the frontside layer deposited in operation 610 has a tensile internal stress, then the first backside layer deposited also has a tensile internal stress. In another example, if the frontside layer deposited in operation 610 has a compressive internal stress, then the first backside layer deposited also has a compressive internal stress. In some embodiments, the magnitude of the internal stress of the deposited first backside layer may be about the same magnitude of the internal stress of the deposited frontside layer. In some embodiments, the magnitude of the internal stress of the deposited first backside layer may greater than the magnitude of the internal stress deposited on the backside layer. By depositing a backside layer with internal stress equal to or greater than the internal stress of the frontside layer, the backside layer counteracts bow that may be induced by the frontside layer. The amount of bow in the compensated wafer depends on the requirements of the process. Typically, a bow compensating film manages wafer bow to be close to neutral overall stress. In some embodiments, the bow of the wafer is reduced such that the bow of the wafer is about 200 μm or less. In some embodiments, the wafer may be substantially flat, i.e., the wafer has a bow of about 150 μm or less. In some embodiments, the bow of the wafer may change directions, e.g., the bow changes from a dome shape to a dish shape.

The first backside layer may be deposited using CVD, PECVD, ALD, epitaxy, PVD, or other deposition process. The first backside layer may be deposited using a special purpose backside deposition apparatus. In some embodiments, the wafer switches chambers between operation 610 and operation 620. The backside deposition apparatus may be a different deposition apparatus then the apparatus used to deposit the one or more frontside layers.

In operation 630, a second backside layer, or cap, is deposited on the first backside layer. The second backside layer has a second type of internal stress. The second type of internal stress is different than the first type of internal stress in the frontside layer and the first backside layer. For example, if the first type of stress is a tensile stress, the second type of stress is a compressive stress. In this example, both the frontside layer and the first backside layer have a tensile internal stress and the second backside layer has a compressive internal stress. In a second example, the first type of stress is a compressive stress and thus the second type of stress is a tensile stress. In the second example, the frontside layer and the first backside layer both have a compressive internal stress, while the second backside layer has a tensile internal stress. The magnitude of the bow induced by the second backside layer may be less than the magnitude of the bow induced by the first backside layer, e.g., about 50% or less, about 30% or less, about 20% or less, or about 10% or less. The bow induced by the second backside layer and the first backside layer may be the sum of the individual induced bows. In some embodiments, bow magnitude of the combined backside layers may be about the same as the bow magnitude of the one or more frontside layers. In some embodiments, the bow contributions of all frontside and backside layers may combine so that the total bow of the wafer is minimal (i.e., less than 100 μm.) For example, the frontside layer(s) may induce a tensile bow of about 400 μm, while the first backside layer may induce a tensile bow of about 450 μm. In this example, the second backside layer may induce a compressive bow of about 50 μm.

Note that references to bow values induced or caused by individual backside layers assume that the bow is uncompensated by other layers. For example, when referring to the magnitude of a bow caused by a first backside layer, we assume that is the bow that would be produced on the substrate if no other layers were present, e.g., no frontside layers. The magnitude of a bow induced by a layer depends on both the internal stress of the material in the layer and the thickness of the layer.

In certain embodiments, the magnitude of bow value produced the first backside layer may be greater than the magnitude of the bow value produced by the one or more frontside layers. In certain embodiments the magnitude of bow value produced the first backside layer may be greater than the magnitude of the bow value produced by the second backside layers.

Returning to FIG. 6, the second backside layer may be deposited in the same apparatus used to deposit the first backside layer in operation 620. In some embodiments, the wafer may stay in the same station for the first backside deposition in operation 620 and the second backside deposition in operation 610.

In operation 640, the wafer is exposed to a thermal cycle. For example, the semiconductor substate may be exposed to a temperature of about 650 to 1100° C. The thermal cycle may cause the wafer to experience a bow shift. However, the second backside layer may minimize the amount of bow shift experienced by the wafer. In some embodiments, the bow shift after depositing a second backside layer is less than about 50% or less than about 10% of the original wafer bow.

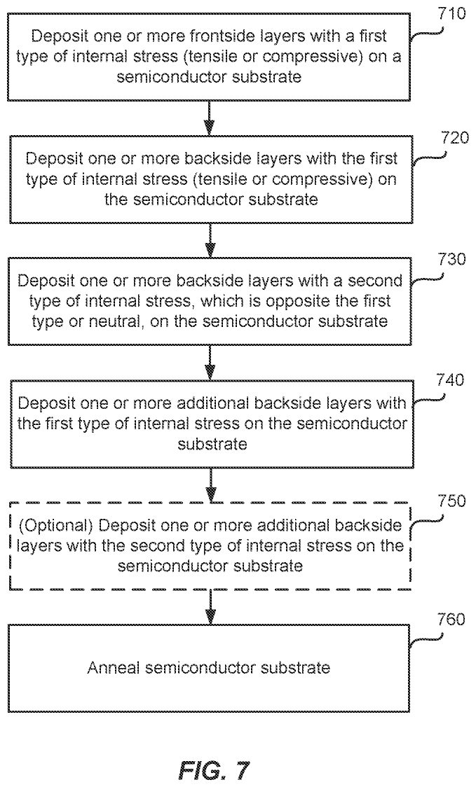

FIG. 7 shows a second example process using multiple backside layers to prevent cracking of layers and/or other bow-related issues during a thermal cycle. FIG. 7 starts with depositing one or more frontside layers with a first type of internal stress (tensile or compressive) on a wafer in operation 710. The internal stress from the frontside layer causes the wafer to bow. As used herein, a first type of internal stress refers to an internal stress that may be either a tensile or compressive stress. A second type of internal stress refers to an internal stress that is either a tensile or compressive stress which is not the first type stress, e.g., if the first type of internal stress is a tensile stress, then the second type of stress is a compressive stress.

Once a frontside layer is deposited onto the wafer, a first backside layer having the first type of internal stress onto the wafer in operation 720. The internal stress of the backside layer is the same type of internal stress of the frontside layer deposited in operation 710. The internal stress of the first backside layer counteracts the internal stress from the frontside layer and may help reduce wafer bow.

In operation 730, a second backside layer is deposited on the first backside layer. The second backside layer has a second type of internal, which is neutral or opposite to the internal stress of the frontside layer and the first backside layer. As discussed above in operation 630, the second backside layer may act as a cap to the first backside layer. The second backside layer may help reduce the amount of bow shift due to a thermal cycle and reduce the chance of cracking of any layers.

In operation 740 a third backside layer is deposited onto the second backside layer. The third backside layer has a first type of internal stress. In other words, the third backside layer has a stress that is the same as the stress of the frontside layer and the first backside layer but opposite to the stress of the second backside layer. Similar to the first backside layer, the internal stress of the third backside layer counteracts the stress introduced from the frontside layer.

After the third backside layer is deposited, an optional operation of depositing a fourth backside layer on the third backside layer may be performed in operation 750. The fourth backside layer has the second type of internal stress and may act as a cap to the third backside layer. Similarly to the second backside layer deposited in operation 730, the fourth backside layer may act as a cap to the third backside layer and reduce the amount of bow shift due to a thermal cycle and reduce the chance of cracking of any layers. In some embodiments, this operation is not performed, and the third backside layer is the outermost layer on the wafer backside.

In a first example, the first type of internal stress is a tensile stress, and the second type of internal stress is a compressive stress. In this example, the frontside layer, the first backside layer and third backside layer have a tensile internal stress, and the second backside layer and the fourth backside layer (if deposited) have a compressive internal stress. For example, the first backside layer may have silicon nitride and the second backside layer may have silicon oxide. In this example, the third backside layer may also have a silicon nitride and the fourth backside layer may have silicon oxide.

In a second example, the first type of internal stress is a compressive stress, and the second type of internal stress is a tensile stress. In this example, the frontside layer, the first backside layer and third backside layer have a compressive internal stress, and the second backside layer and the fourth backside layer (if deposited) have a tensile internal stress. For example, the first backside layer may have silicon oxide and the second backside layer may have silicon nitride. In this example, the third backside layer may also have a silicon oxide and the fourth backside layer may have silicon nitride.

The magnitude of the bow induced by each layer may be controlled to manage the overall bow of the substrate. For example, the magnitude of the stress from the sum of the deposited backside layers may be equivalent to the magnitude of the stress of the frontside layer(s). When the net difference in amount of bow from the frontside layers and the amount of bow from the deposited backside layers is relatively low, e.g., a difference of about 0 to 30%, the overall wafer bow may be minimal or acceptable for further processing.

In each of the backside deposition operations, 720-750, each of the deposition layers may be deposited by a backside deposition apparatus. In some embodiments, the wafer may stay in the same chamber for operations 720-750. In some embodiments, the wafer may switch chambers between operation 710 and operation 720. The backside deposition apparatus may be a different deposition apparatus then the apparatus used to deposit the one or more frontside layers. For example, the wafer may be in a first chamber for the deposition of the frontside layer in operation 710, and the wafer may be moved to a second chamber for the deposition of each backside layer in operations 720-740.

In operation 760, the wafer is exposed to a thermal cycle, similar to the thermal cycle described above in operation 640 in FIG. 6. The thermal cycle may cause the wafer to experience a bow shift. However, the second backside layer and the fourth backside layer (if deposited) may minimize the amount of bow shift experienced by the wafer during the thermal cycle. In some embodiments, the bow shift may be less than about 10% of the original bow

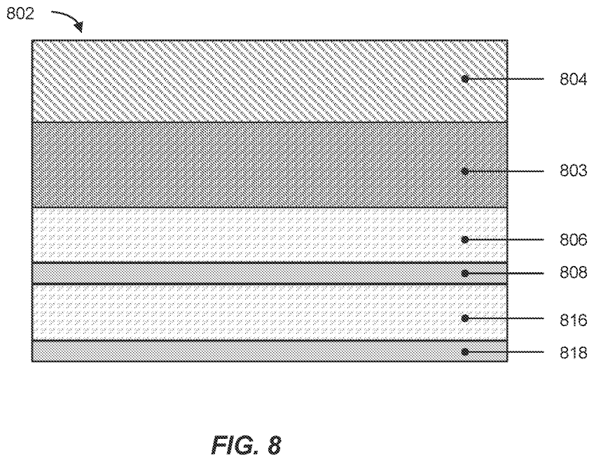

FIG. 8 shows an example cross section of a wafer 802 after undergoing the example process in FIG. 7. The wafer 802 has a main structure 803 (e.g., a single crystal silicon substrate). A frontside layer 804 is deposited on a frontside of the main structure 803. The frontside layer 804 has a first type of internal stress. The first type of internal stress may be either a tensile internal stress or compressive internal stress. A first backside layer 806 is deposited on a backside of the main structure 803. The first backside layer 806 has the first type of internal stress, e.g., the same internal stress as the frontside layer. A second backside layer 808 is deposited on the first backside layer 806. The second backside layer 808 has an internal stress of a second type. The second type of internal stress either a tensile internal stress or a compressive internal stress and is opposite of the first type of stress, e.g., if the first type of stress is a tensile internal stress, then the second type of stress is a compressive internal stress. The second backside layer 808 has a bow of about 20% or less the bow of the first backside layer. A third backside layer 816 is deposited on the second backside layer 808. The third backside layer 816 has the first type of internal stress. A fourth backside layer 818 is deposited on the third backside layer 816. The second backside layer 818 has an internal stress of the second type.

In a first example, the first type of stress is a tensile internal stress, and the second type of stress is a compressive internal stress. In this example, the frontside layer 804, the first backside layer 806, and the third backside layer 816 have a tensile internal stress. The second backside layer 808 and the fourth backside layer 8018 have a compressive internal stress. In a second example, the first type of stress is a compressive internal stress, and the second type of stress is a tensile internal stress. In this example, the frontside layer 804, the first backside layer 806, and the third backside layer 816 have a compressive internal stress. The second backside layer 808 and the fourth backside layer 8018 have a tensile internal stress.

As discussed above, the internal stress of the frontside layer 804 may cause wafer bow. The internal stress of the backside layers may counteract the internal stress of the frontside layer 804. To minimize wafer bow, the internal stress of the backside layers may be about equal to the internal stress of frontside layer 804. Thus, if the frontside layer 804 has a tensile bow with a magnitude of about 400 μm, the backside layers may have a sum tensile bow with a magnitude of about 400 μm. In a first example, where the frontside layer 804 has a bow of 400 μm, the first backside layer 806 and the third backside layer 816 may each have a tensile bow of about 250 μm, and the second backside layer 808 and the fourth backside layer 818 may each have a compressive bow of about 50 μm. The tensile bow of the first backside layer 806 and the second backside layer 808 sum to have a tensile bow of about 500 MPa. The compressive bow of the second backside layer 808 and the fourth backside layer 818 reduce the tensile bow from the first backside layer 806 and the third backside layer 816. Thus, the tensile bow of 500 μm is reduced by about 100 μm (50 μm from the compressive bow from the second backside layer 808 the compressive bow from the fourth backside layer 818), leaving about 400 μm of tensile bow contributed by the backside layer. The 400 μm tensile internal bow from the frontside layer 804 and the 400 μm tensile bow from the backside layers may cancel each other out and minimize any potential wafer bow.

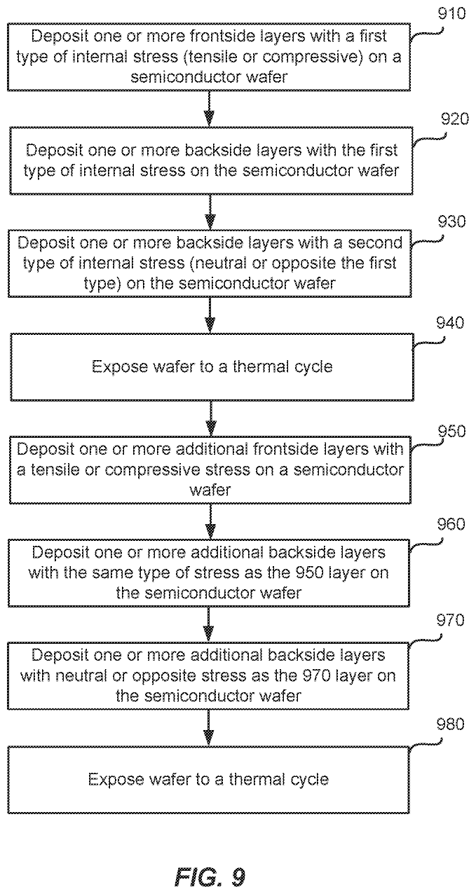

FIG. 9 shows another example process using multiple backside layers to prevent cracking of layers during a thermal cycle. FIG. 9 starts with depositing one or more frontside layers with a first type (tensile or compressive) of internal stress on a wafer in operation 910. The internal stress from the frontside layer may cause the wafer to bow.

Once a frontside layer is deposited onto the wafer, a first backside layer having an internal stress of the first type is deposited onto the wafer in operation 920. The internal stress of the first backside layer is the same type of internal stress of the frontside layer deposited in operation 910. The internal stress of the first backside layer may be used to counteract the internal stress of the frontside layer deposited in operation in 910.

In operation 930, a second backside layer is deposited on the first backside layer. The second backside layer has a second type of internal stress, opposite to the internal stress of the frontside layer and the first backside layer. Similar to discussions above, the second backside layer may act as a cap to the first backside layer. The second backside layer may help reduce the amount of bow shift due to a thermal cycle and reduce the chance of cracking of any layers.

In operation 940, the wafer with one or more frontside layers, a first backside layer, and a second backside layer, is exposed to a thermal cycle. The thermal cycle may cause the wafer to experience a bow shift. However, the second backside layer may minimize the amount of bow shift experienced by the wafer. In some embodiments, the bow shift may be less than about 20% of the original bow.

In operation 950, a second frontside layer is deposited on top of the initial frontside layer. The second frontside layer may have the first type of internal stress or second type of internal stress. The internal stress from the second frontside layer may cause the wafer to bow.

A third backside layer is deposited on the second backside layer in operation 960. The third backside layer has the same type of internal stress as the second frontside layer deposited in the operation before this. For example, if the second frontside layer has the first type of internal stress, the third backside layer has the first type of internal stress. The third backside layer counteracts bow caused by the second frontside layer.

In operation 970, a fourth backside layer optionally is deposited onto the third backside layer. The fourth backside layer has a different internal stress then the internal stress of the third backside layer. For example, if the second frontside layer and the third backside layer have the first type of internal stress, then the fourth backside layer has the second type of internal stress. In one example, if the frontside layer has a tensile internal stress, then the third backside layer has a tensile internal stress. In this example, the fourth backside layer will have a compressive internal stress.

The wafer is exposed to a thermal cycle in operation 980. The thermal cycle may cause the wafer to experience a bow shift. The fourth backside layer may minimize the amount of bow shift experienced by the wafer, reducing the chance of cracking of the deposited layers on the wafer due to the thermal cycle.

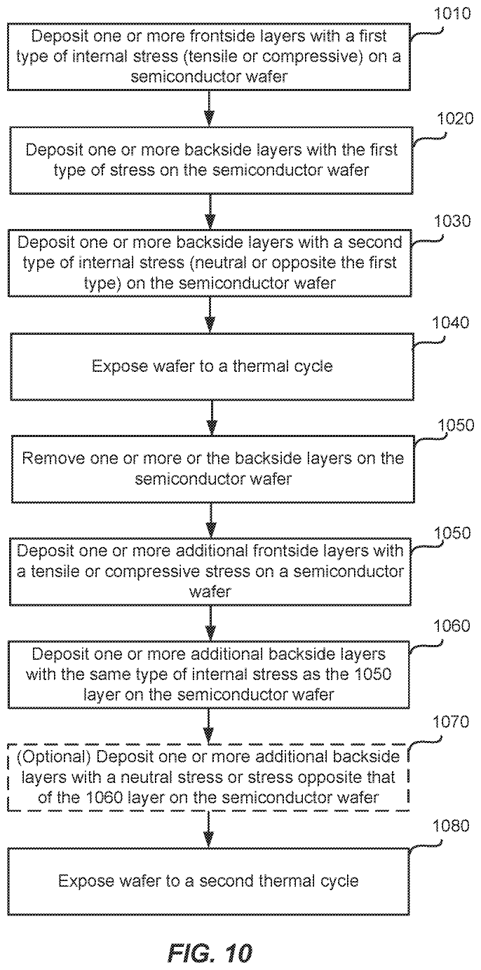

FIG. 10 shows another example process using multiple backside layers to prevent cracking of layers during a thermal cycle. FIG. 10 starts with depositing one or more frontside layers with a first type (tensile or compressive) of internal stress on a wafer in operation 910 similar to that described above in operation in 610. The internal stress from the frontside layer may cause the wafer to bow.

Once a frontside layer is deposited onto the wafer, a first backside layer having an internal stress of the first type is deposited onto the wafer in operation 1020. The internal stress of the first backside layer is the same type of internal stress of the frontside layer deposited in operation 1010. The internal stress of the first backside layer may be used to counteract the internal stress of the frontside layer deposited in operation in 1010.

In operation 1030, a second backside layer is deposited on the first backside layer, The second backside layer has a second type of internal stress, neutral or opposite to the internal stress of the frontside layer and the first backside layer. Similarly to discussions above, the second backside layer may act as a cap to the first backside layer. The second backside layer may help reduce the amount of bow shift due to a thermal cycle and reduce the chance of cracking of any layers.

In operation 1040, the wafer is exposed to a thermal cycle. The thermal cycle may cause the wafer to experience a bow shift. However, the second backside layer may minimize the amount of bow shift experienced by the wafer. In some embodiments, the bow shift may be less than 20% of the original bow.

In operation 1050, the second backside layer is removed. As indicated, the second backside layer may be used to control bow shift during a thermal cycle. Once a thermal cycle is completed, the second backside layer may be removed prior to further processing for the wafer. In some embodiments, the entire second backside layer is removed such that the exposed surface on the backside is the first backside layer deposited in operation 1020. In some embodiments, part of the backside layer is removed.

In operation 1060, a second frontside layer is deposited on top of the initial frontside layer. The second frontside layer may have the first type of internal stress or second type of internal stress. The internal stress from the second frontside layer may cause the wafer to bow.

A third backside layer is deposited on the first backside layer in operation 1070. The third backside has the same type of internal stress as the second frontside layer deposited in operation 1060. For example, if the second frontside layer has the first type of internal stress, the third backside layer has the first type of internal stress. The third backside layer counteracts bow caused by the second frontside layer.

After the third backside layer is deposited, an optional operation of depositing a fourth backside layer on the third backside layer may be performed in operation 1070. The fourth backside layer has an internal stress that is neutral or opposite to the internal stress deposited in operation 1060. For example, if the second frontside layer and the third backside layer have the first type of internal stress, then the fourth backside layer has the second type of internal stress. Similar to the second backside layer deposited in operation 1030, the fourth backside layer may act as a cap to the third backside layer and reduce the amount of bow shift due to a thermal cycle and reduce the chance of cracking of any layers. In some embodiments, this operation is not performed, and the third backside layer is the outermost layer on the wafer backside.

The wafer is exposed to a thermal cycle in operation 1080. The thermal cycle may cause the wafer to experience a bow shift. If the fourth backside layer is deposited, the fourth backside layer may minimize the amount of bow shift experienced by the wafer, reducing the chance of cracking of the deposited layers on the wafer due to the thermal cycle.

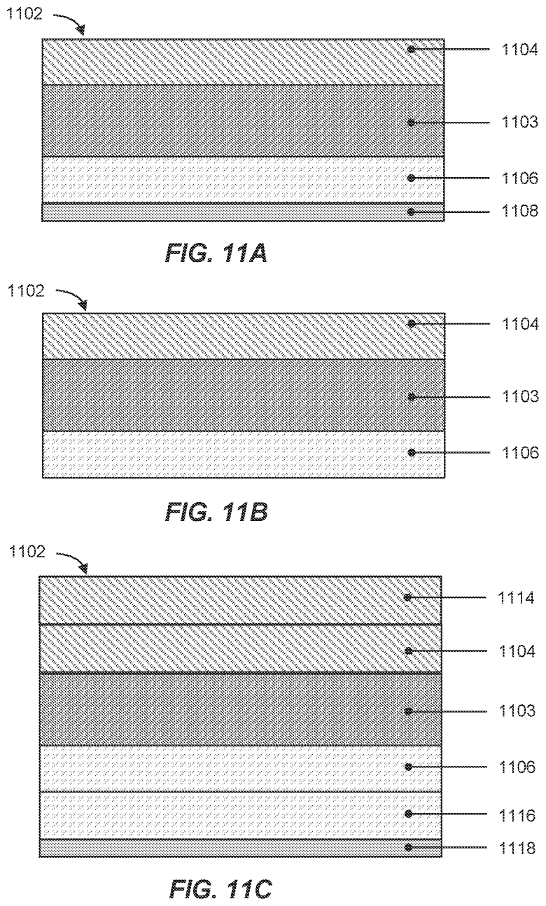

FIGS. 11A-11C show an example cross section of a wafer 1102 after different operations from the example process in FIG. 10. FIG. 11A shows the cross section of the wafer 1102 after the second backside layer is deposited in operation 1030. The wafer 1102 has a main structure 1103 (e.g., a single crystal silicon substrate). A frontside layer 1104 is deposited on a frontside of the main structure 1103. The frontside layer 1104 has a first type of internal stress. A first backside layer 1106 is deposited on a backside of the main structure 1103. The first backside layer 1106 has the first type of internal stress, e.g., the same internal stress as the frontside layer. A second backside layer 1108 is deposited on the first backside layer 1106. The second backside layer 1108 has an internal stress of a second type. The second type of internal stress is neutral or opposite that of the first type of stress, e.g., if the first type of stress is a tensile internal stress, then the second type of stress may be a compressive internal stress.

FIG. 11B shows the wafer 1102 after at least part of the second backside layer is removed in operation 1050. In the embodiment shown, the entire second backside layer from FIG. 11A is removed. After the second backside layer is removed, the wafer 1102 has the main structure 1103 with the frontside layer 1104 and the first backside layer 1106. Each of the remaining layers has the first type of internal stress which counteract the internal stress from the other, reducing wafer bow.

FIG. 11C shows the wafer 1102 after the fourth backside layer is deposited in operation 1070. On top of the frontside layer 1104 is a second frontside layer 1114. A third backside layer 1116 is deposited on the first backside layer 1106. The third backside layer 1116 has the same internal stress as the second frontside layer 1114. A fourth backside layer 1118 is on the third backside layer 1116. The fourth backside layer has a neutral internal stress or a stress that is the opposite internal stress as the third backside layer 1116 and reduces bow shift during a thermal cycle.

In a first example, the first type of stress is a tensile internal stress, and the second type of stress is a compressive internal stress. In this example, the frontside layer 1104, the second frontside layer 1114, the first backside layer 1106, and the third backside layer 1116 may have a tensile internal stress. The fourth backside layer 1118 may have a compressive internal stress. In a second example, the first type of stress is a compressive internal stress, and the second type of stress is a tensile internal stress. In this example, the frontside layer 1104, the second frontside layer 1114, the first backside layer 1106, and the third backside layer 1116 have a compressive internal stress. The fourth backside layer 1118 has a tensile internal stress.

### Apparatus

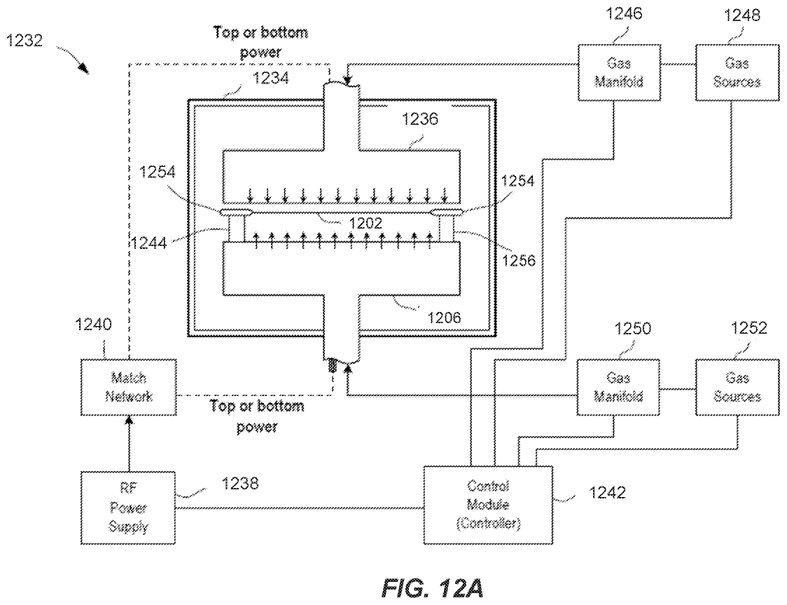

FIG. 12A is a block diagram that illustrates a substrate processing system 1200 used to perform processing on a wafer 1202 (also referred to as a wafer), according to some embodiments. As shown, the substrate processing system may include a chamber 1234. A center column may be configured to support a pedestal for when a top surface of the wafer 1202 is being processed, e.g., a film is being formed on the top surface of the wafer 1202, or on the backside of the wafer 1202. The pedestal, in accordance with some embodiments disclosed herein, may be referred to as a showerhead-pedestal (“ShoPed”) 1206. A showerhead 1236 may be disposed over the ShoPed 1206.

In some embodiments, the showerhead 1236 may be electrically coupled to power supply 1238 via a match network 1240. The power supply 1238 may be controlled by a control module 1242, e.g., a controller. In some embodiments, power may be provided to the ShoPed 1206 instead of the showerhead 1236. The control module 1242 may be configured to operate the substrate processing system 1232 by executing process input and control for specific process recipes. Depending on whether the top surface of the wafer 1202 is receiving a deposited film or the bottom surface of the wafer 1202 is receiving a deposited film, the controller module 1242 may set various operational inputs for a process recipe, such as power levels, timing parameters, process gasses, mechanical movement of a wafer 1202, and/or the height of the wafer 1202 relative to the ShoPed 1206.

In some embodiments, the center column may also include lift pins, which are controlled by a lift pin control. Such lift pins may be used to raise the wafer 1202 from the ShoPed 1206 to allow an end effector (not shown) to pick the wafer and to lower the wafer 1202 after being placed by the end effector. The end effector may also place the wafer 1202 over spacers 1244. As will be described below, the spacers 1244 may be sized to provide a controlled separation of the wafer 1202 between a top surface of the showerhead 1236 (facing the wafer) and a top surface of the ShoPed 1206 (facing the wafer).

In some embodiments, the substrate processing system 1232 may further include a first gas manifold 1246 that is connected to first gas sources 1248, e.g., gas chemistry supplies from a facility and/or inert gases. Depending on the processing being performed over a top surface of the wafer 1202, the control module 1242 may controls the delivery of first gas sources 1248 via the first gas manifold 1246. The chosen gases may then be flown into the showerhead 1236 and distributed in a space volume defined between a face of the showerhead 1236 that faces that wafer 1202 when the wafer is resting over the pedestal.

In some embodiments, the substrate processing system 1232 may further include a second gas manifold 1250 that is connected to second gas sources 1252, e.g., gas chemistry supplies from a facility and/or inert gases. Depending on the processing being performed over a bottom surface of the wafer 1202, the control module 1242 may control the delivery of second gas sources 1252 via the second gas manifold 1250. The chosen gases may then be flown into the showerhead 1236 and distributed in a space volume defined between a face of the ShoPed 1206 that faces an under surface or under side (e.g., backside) of the wafer 1202 when the wafer is resting over the spacers 1244. The spacers 1244 may provide for a separation that optimizes deposition to the under surface of the wafer 1202, while reducing deposition over the top surface of the wafer 1202. In some embodiments, while deposition is targeted for the under surface of the wafer 1202, an inert gas may be flown over the top surface of the wafer 1202 via the showerhead 1236, which may push reactant gases away from the top surface and enable reactant gases provided from the ShoPed 1206 to be directed to the under surface of the wafer 1202.

Further, the gases may be premixed or not. Appropriate valving and mass flow control mechanisms may be employed to ensure that the correct gases are delivered during the deposition and plasma treatment phases of the process. Process gases may exit the chamber 1234 via an outlet. A vacuum pump (e.g., a one or two stage mechanical dry pump and/or a turbomolecular pump) may draw process gases out and maintains a suitably low pressure within the reactor by a close loop-controlled flow restriction device, such as a throttle valve or a pendulum valve.

In some embodiments, a carrier ring 1254 may encircle an outer region of the ShoPed 1206. When the top surface of the wafer 1202 is being processed, e.g., a material is being deposited thereon, the carrier ring 1254 may be configured to sit over a carrier ring support region that is a step down from a wafer support region in the center of the ShoPed 1206. The top surface of the carrier ring 1254 is generally coplanar with the top surface of the wafer 1202. The carrier ring 1254 may include an outer edge side of its disk structure, e.g., outer radius, and a wafer edge side of its disk structure, e.g., inner radius, that is closest to where the wafer 1202 sits. The carrier ring 1254 may be associated with an inner diameter (ID). The inner diameter may extend to an inner perimeter of the carrier ring and generally surround a substrate (e.g., wafer 1202) in a processing chamber. The wafer edge side of the carrier ring 1254 may also include a plurality of contact support structures or “tabs” which may be configured to lift the wafer 1202 when the carrier ring 1254 is held by the spacers 1244. The carrier ring 1254 may include a plurality of tabs with a quantity selected from a range to support the wafer 1202 during processing. Additional details regarding embodiments of the tabs will follow.

FIG. 12B is a block diagram that illustrates another substrate processing system 1232 used to perform processing on the wafer 1202, according to some embodiments. In some embodiments, spider forks 1256 may be used to lift and maintain the carrier ring 1254 in its process height, e.g., to allow depositing in the under surface (backside) of the wafer 1202. The carrier ring 1254 may therefore be lifted along with the wafer 1202. In some implementations, the carrier ring 1254 may be rotated to another station, e.g., in a multi-station system.

Broadly speaking, the embodiments disclosed herein are for a system to deposit PECVD films on the selective side of the wafer (front and/or back) with dynamic control. Some embodiments may include a dual gas-flowing electrode for defining a capacitively-coupled PECVD system. The system may include a gas-flowing showerhead (e.g., showerhead 1236) and a ShoPed 126. In some embodiments, the gas-flowing pedestal (i.e., ShoPed) is a combination showerhead and pedestal, which enables deposition on a back-side of the wafer. The electrode geometry combines features of a showerhead, e.g., a gas mixing plenum, holes, hole-pattern, gas jet preventing baffle, and features of a pedestal. Examples of features of a pedestal include an embedded controlled heater, wafer-lift mechanisms, ability to hold plasma suppression rings, and movability. This enables the transfer of wafers and the processing of gasses with or without RF power from the pedestal.

In some embodiments, the system may have a wafer lift mechanism that tightly controls parallelism of the substrates against the electrodes. In one example, this may be achieved by setting up the lift mechanism parallel to the two electrodes and controlling manufacturing tolerances, e.g., spindle or lift pins mechanisms. In another example, the lift may be achieved by raising the wafer lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and deposition film properties. The system may further allow selective enabling/disabling of the side where reactants are flown. One side can flow the reactant and the other side can flow inert gases to suppress the deposition and plasma.

In some embodiments, the gap between the side of the wafer that does not need plasma/dep may be tightly controlled. This distance may be controlled to suppress plasma. By not controlling the distance, the wafer may be susceptible to plasma damage. For example, the system may allow a minimal gap from about 2 mm to about 0.5 mm, and in another embodiment from about 1 mm to about 0.05 (limited by the wafer bow), and such gap can be controlled. The gap maybe controlled depending on process conditions.

In some embodiments, the gas-flowing pedestal (i.e., ShoPed) may enable, without limitation: (a) thermal stabilization of the wafer to processing temperature prior to processing; (b) selective design of hole patterns on the ShoPed to selectively deposition film in different areas of the back-side of the wafer; (c) swappable rings can be attached to achieve appropriate plasma confinement and hole pattern, (d) stable wafer transfer mechanisms within chamber and for transferring wafer outside to another chamber or cassette-such as lift pins, RF-coupling features, minimum-contact arrays; (e) implement gas mixing features, e.g., such as inner plenum, baffle and manifold lines openings; and (f) add compartments in the gas-flowing pedestal (i.e., ShoPed) to enable selective gas flow to different regions of the back side of the wafer and control flow rates via flow controllers and/or multiple plenums.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the wafer, film edge exclusion control is highly desirable to avoid lithography-related overlay problems. The lift mechanism used in this system is done via a carrier ring 124 that has a design feature to shadow the deposition on the edge. This specifies the edge exclusion control via the design and shape of the carrier ring.

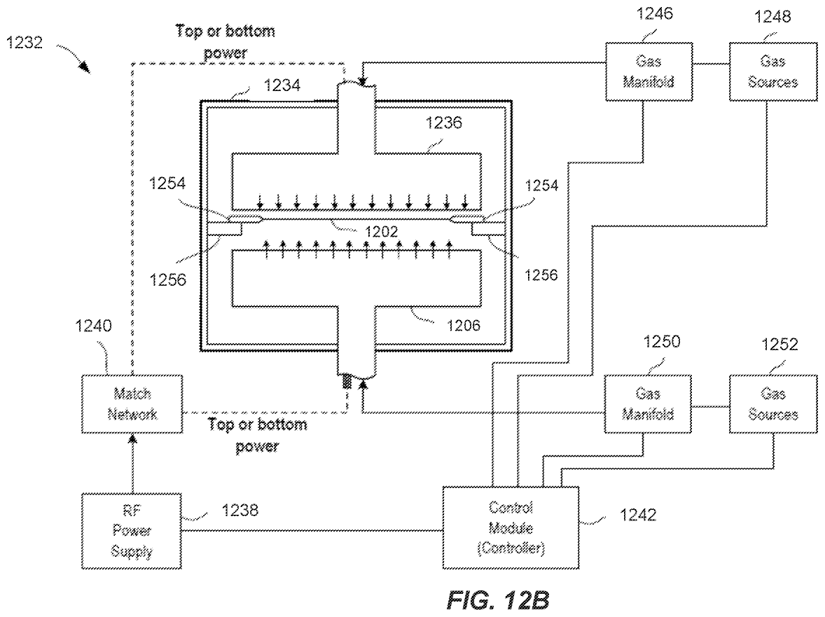

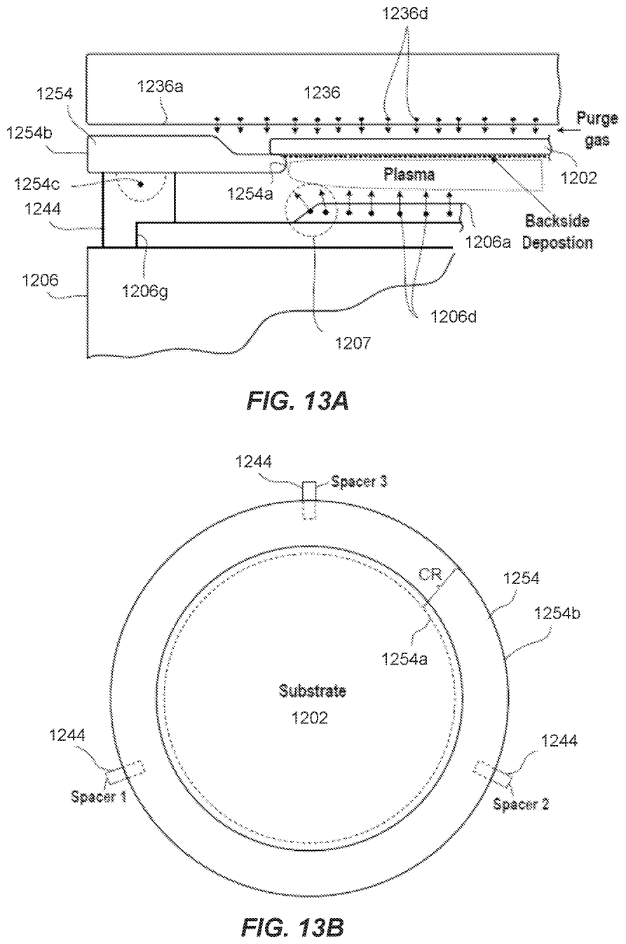

FIG. 13A shows a cross-sectional view of an edge region of the ShoPed 1206. This view provides a cross-sectional representation of the carrier ring 1254, which has a carrier ring inner radius 1254a and a carrier ring outer radius 1254b. In some embodiments, the carrier ring 1254 includes support extensions 1254c, which extend below the substantial flat surface of the carrier ring 1254.

The support extensions 1254c are configured to mate and sit within support surfaces defined into a top surface of the spacers 1244. The support surfaces provide a complementary mating surface for the support extensions 1254c, such that the carrier ring 1254 is prevented from sliding or moving when supported by the spacers 1244. Although three spacers are shown as spacers 1244 are shown in FIG. 13B, it is envisioned that any number of spacers may be provided, so long as the carrier ring can be supported substantially parallel to the surface of the ShoPed 1206, and spacing is defined for supporting wafer 1202 at a spaced apart relationship from a top surface of the ShoPed 1206.

Further shown is that a top surface of the ShoPed 1206 will include a hole pattern 1206a that is distributed throughout the surface to provide even distribution and output of gases during operation. In one embodiment, the hole pattern 1206a is distributed in a plurality of concentric rings that start at the center of the top surface of the ShoPed 1206 and extend to an outer periphery of the ShoPed 1206. At least one hole pattern 1206a is provided at an edge hole region 1207 of the hole pattern, and orifices defined in the edge hole region 1207 are preferably angled to provide gases non-perpendicular to the surface of the ShoPed 1206.

In one example, the angle or tilt at which the orifices in the edge hole region 1207 is defined to tilt or angle away from the center of the ShoPed 106. In one embodiment, the angle is approximately 45° from horizontal. In other embodiments, the angle can vary between 20° from horizontal to about 80° from horizontal. In one embodiment, by providing the angled orifices in the edge hole region 1207, additional distribution of process gases can be provided during backside deposition of the wafer 1202. In one embodiment, the remainder orifices 1206d of the hole pattern 1206a are oriented substantially perpendicular to the surface of the ShoPed 106 and directed toward the underside of the wafer 1202.

FIG. 13B illustrates that when the wafer 1202 is held by the carrier ring 1254, the wafer 1202 edge will sit on an edge region closer to the carrier ring inner radius 1254a of the carrier ring 1254. The surface of the showerhead 1236 facing the top surface of the wafer 1202, when positioned using spacers 1244, may be substantially close to prevent deposition during a mode where deposition is being carried out to the backside of the wafer 1202.

By way of example, the distance between the top of the wafer 1202 and the surface of the showerhead 1236 is preferably between about 2 mm to about. 5 mm, and in some embodiments about 1 mm to about 0.5 mm, depending on the wafer bow. That is, if the wafer is bowed substantially, the separation will be about 0.5 mm or larger. If the wafer is not yet bowed substantially, the separation can be less than about 0.5 mm. In one embodiment, it is preferable that the separation be minimized to prevent deposition on the top side of the substrate when the backside of the substrate is being deposited with a layer of material. In some embodiments, the showerhead 1236 is configured to supply an inert gas flow over the top side of the wafer 1202 during when the backside of the substrate is being deposited and deposition gases are being supplied by the ShoPed 1206.

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexafluoride (WF₆) may be introduced in alternating pulses to the surface of the semiconductor substrate, at the first station, using an individual gas supply system that creates a localized atmosphere at the substrate surface. Another station may be used for NF₃ treatment, and a third and/or fourth for subsequent ALD bulk fill.

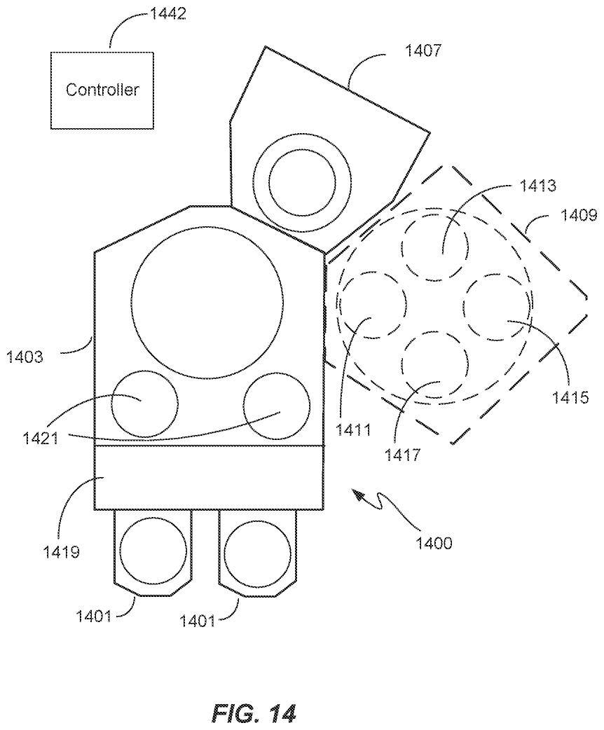

FIG. 14 is a schematic of a process system suitable for conducting deposition processes in accordance with embodiments. The system 1400 includes a transfer module 1403. The transfer module 1403 provides a clean, pressurized environment to minimize risk of contamination of substrates being processed as they are moved between various reactor modules. Mounted on the transfer module 1403 is a multi-station reactor 1409 capable of performing ALD, treatment, and CVD according to various embodiments. Multi-station reactor 1409 may include multiple stations 1411, 1413, 1415, and 1417 that may sequentially perform operations in accordance with disclosed embodiments. For example, multi-station reactor 1409 may be configured such that station 1411 performs a frontside deposition using a precursor and a reducing agent, station 1413 performs an ALD bulk deposition of a conformal layer using a reducing agent, station 1415 performs a NF₃ treatment operation, and station 1417 may perform a bulk ALD fill after treatment using a reducing agent.

Stations may include a heated pedestal or substrate support, one or more gas inlets or showerhead or dispersion plate.

Returning to FIG. 14, also mounted on the transfer module 1403 may be one or more single or multi-station modules 1407 capable of performing plasma or chemical (non-plasma) pre-cleans, other deposition operations, or etch operations. The module may also be used for various treatments to, for example, prepare a substrate for a deposition process. The system 1400 also includes one or more wafer source modules 1401, where wafers are stored before and after processing. An atmospheric robot (not shown) in the atmospheric transfer chamber 1419 may first remove wafers from the wafer source modules 1401 to loadlocks 1421. A wafer transfer device (generally a robot arm unit) in the transfer module 1403 moves the wafers from loadlocks 1421 to and among the modules mounted on the transfer module 1403.

In various embodiments, a system controller 1442 is employed to control process conditions during deposition. The system controller 1442 will typically include one or more memory devices and one or more processors. A processor may include a CPU or computer, analog and/or digital input/output connections, stepper motor controller boards, etc.

The system controller 1442 may control all the activities of the deposition apparatus. The system controller 1442 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the system controller 1442 may be employed in some embodiments.

Typically there will be a user interface associated with the system controller 1442. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 1442. The signals for controlling the process are output on the analog and digital output connections of the system 1400.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a system controller 1442 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1442, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1442, in some implementations, may be a part of or coupled to a computer that is integrated with, coupled to the system, otherwise networked to the system, or a combination thereof. For example, the system controller 1442 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The system controller 1442 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of processing a substrate during fabrication of an electronic device, the method comprising:
(a) depositing one or more frontside layers on a frontside of the substrate, wherein the one or more frontside layers induce a bow in the substrate;
(b) depositing a first backside layer on a backside of the substrate, wherein the first backside layer reduces the bow in the substrate, wherein the first backside layer and the one or more frontside layers have internal stresses of a first type;
(c) depositing a second backside layer over the first backside layer, wherein the second backside layer has an internal stress of a second type, which is opposite the first type or is neutral; and
(d) after (c), exposing the substrate to a thermal process that increases temperature of the substrate to at least about 600° C.

2. The method of claim 1, wherein the bow of the substrate is about 300 μm or more.

3. The method of claim 1, wherein the bow of the substrate is about 400 μm or more.

4. The method of claim 1, wherein at least one of the one or more frontside layers comprise a hardmask.

5. The method of claim 1, wherein the one or more frontside layers comprise a stack of about 100 or more alternating layers.

6. The method of claim 5, wherein the stack comprises alternating oxide layers and nitride or polysilicon layers.

7. The method of claim 1, wherein the internal stress of the first type is a tensile stress and the internal stress of the second type is a compressive stress.

8. The method of claim 1, wherein a first bow magnitude that would be produced by the first backside layer is larger, if uncompensated, than a second bow magnitude, if uncompensated, that would be produced by the second backside layer.

9. The method of claim 1, wherein the first backside layer comprises silicon nitride.

10. The method of claim 1, wherein the first backside layer has a thickness of about 0.1 μm to about 5 μm.

11. The method of claim 1, wherein the second backside layer comprises silicon oxide.

12. The method of claim 1, wherein the second backside layer has a thickness of about 0.01 μm to about 1 μm.

13. The method of claim 1, wherein the thermal process in (d) is an annealing process.

14. The method of claim 1, wherein the thermal process in (d) comprises deposition of a hardmask on the frontside of the substrate.

15. A substrate comprising:
(a) one or more frontside layers on a frontside of the substrate;
(b) a first backside layer on a backside of the substrate, wherein the first backside layer and the one or more frontside layers have internal stresses of a first type; and
(c) a second backside layer over the first backside layer, wherein the second backside layer has an internal stress of a second type, opposite that of the internal stress or neutral.

16. An apparatus for semiconductor processing, the apparatus comprising:
a process chamber;
a substrate support within the process chamber;
a showerhead;
a gas source fluidically connected to the showerhead; and
a controller configured to cause:
(i) receiving a substrate comprising one or more frontside layers that cause bow in the substrate;
(ii) depositing a first backside layer on a backside of the substrate, which first backside layer reduces bow in the substrate, wherein the first backside layer and one or more frontside layers have internal stresses of a first type; and
(iii) depositing a second backside layer over the first backside layer, wherein the second backside layer has a neutral internal stress or an internal stress of a second type, opposite that of the first type.
